(19) United States
(12) Patent Application Publication
(10) Pub. No.: US 2026/0136601 A1
(43) Pub. Date: May 14, 2026

(54) SEMICONDUCTOR DEVICE INCLUDING SOURCE/DRAIN FORMED BY BOTTOM-UP GROWTH PROCESS AND METHOD FOR MANUFACTURING THE SAME

(71) Applicant: Taiwan Semiconductor Manufacturing Company, Ltd., Hsinchu (TW)

(72) Inventors: Tsung-Han CHUANG, Hsinchu (TW); Jung-Hung CHANG, Hsinchu (TW); Shih-Cheng CHEN, Hsinchu (TW); Wen-Ting LAN, Hsinchu (TW); Kuo-Cheng CHIANG, Hsinchu (TW); Chih-Hao WANG, Hsinchu (TW)

(73) Assignee: Taiwan Semiconductor Manufacturing Company, Ltd., Hsinchu (TW)

(21) Appl. No.: 18/945,648

(22) Filed: Nov. 13, 2024

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 84/0128; H10D 84/013; H10D 84/038; H10D 84/83

(57) ABSTRACT

A method for manufacturing a semiconductor device includes: forming a stack structure on a substrate, the stack structure including a plurality of sacrificial layer portions and a plurality of channel layer portions which are alternately stacked; forming a trench that penetrates the stack structure and that terminates at an upper surface of the substrate; forming a base layer in the trench; forming an intermediate layer on the base layer and in the trench, the intermediate layer including a bottom portion and two side portions that extend from the bottom portion and that are spaced apart from each other, each of the two side portions including an upper part and a lower part interconnected to the upper part and the bottom portion; removing the upper part of each of the two side portions of the intermediate layer; and forming an upper layer over the intermediate layer.

### BACKGROUND

With continuous development of semiconductor technology, transistors (e.g., p-channel metal-oxide-semiconductor (PMOS) transistors or n-channel metal-oxide-semiconductor (NMOS) transistors) have wide applications due to superior electrical performance. In order to meet various application needs, the semiconductor industry is devoted to improving the electrical performance of the transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are flow diagrams illustrating a method for manufacturing a semiconductor device in accordance with some embodiments.

FIGS. 2A to 20 are schematic views illustrating some intermediate stages of the method as depicted in FIGS. 1A and 1B in accordance with some embodiments.

FIG. 21 is a schematic view illustrating a semiconductor device in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” “uppermost,” “lowermost,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

Nanosheet semiconductor devices (e.g., nanosheet field-effect transistors (FETs)) have been applied in various electrical products due to superior electrical performance. A nanosheet FET structure is one type of a gate-all-around FET (GAAFET) structure. Regarding a p-type nanosheet FET, strain (e.g., compressive strain) of a transistor channel is conducive to improving electrical performance because such strain can enhance hole mobility in the transistor channel. In addition, it is known that compared with being formed on a (100) silicon wafer, a p-type nanosheet FET formed on a (110) silicon wafer has a better electrical performance (e.g., a direct current (DC) performance).

In a p-type nanosheet FET, source/drain regions formed by a bottom-up growth process have more strain (e.g., compressive strain), and thus has attracted attention compared to source/drain regions formed by a process in which sidewall merge of epitaxial layers of the source/drain regions is induced. Nevertheless, formation of the source/drain regions of the p-type nanosheet FET by the bottom-up growth process is difficult to be achieved on the (110) silicon wafer, compared to formation thereof on the (100) silicon wafer.

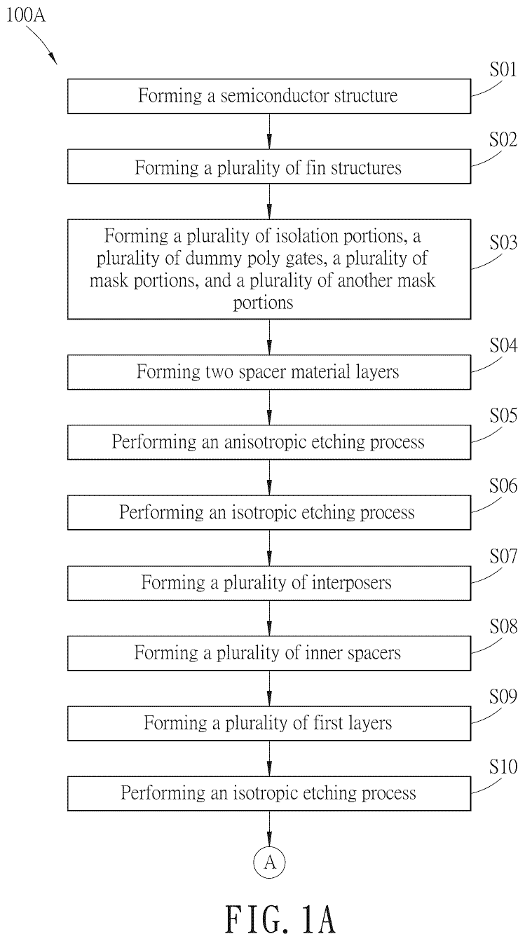

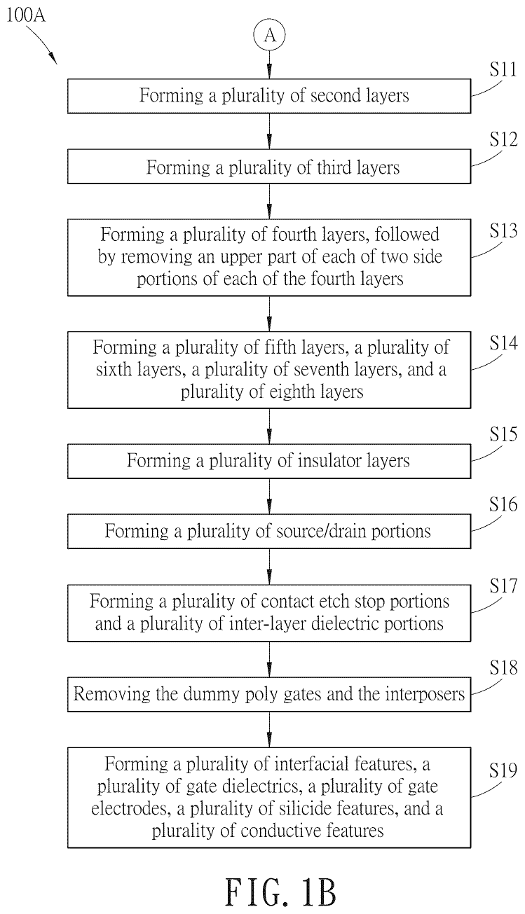

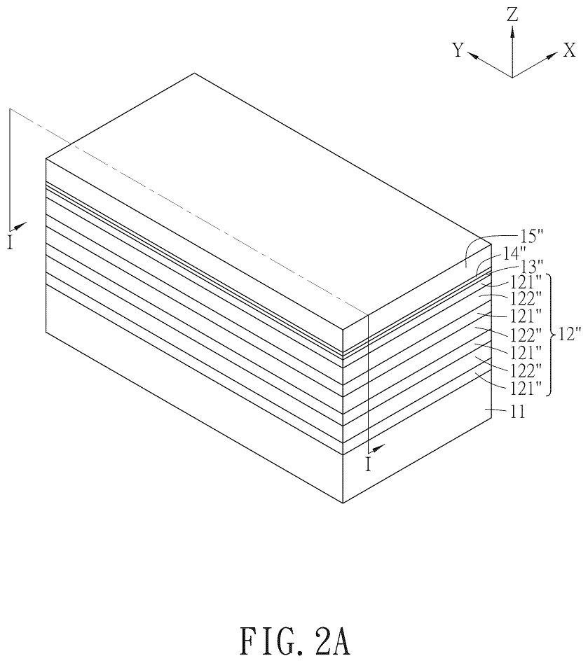

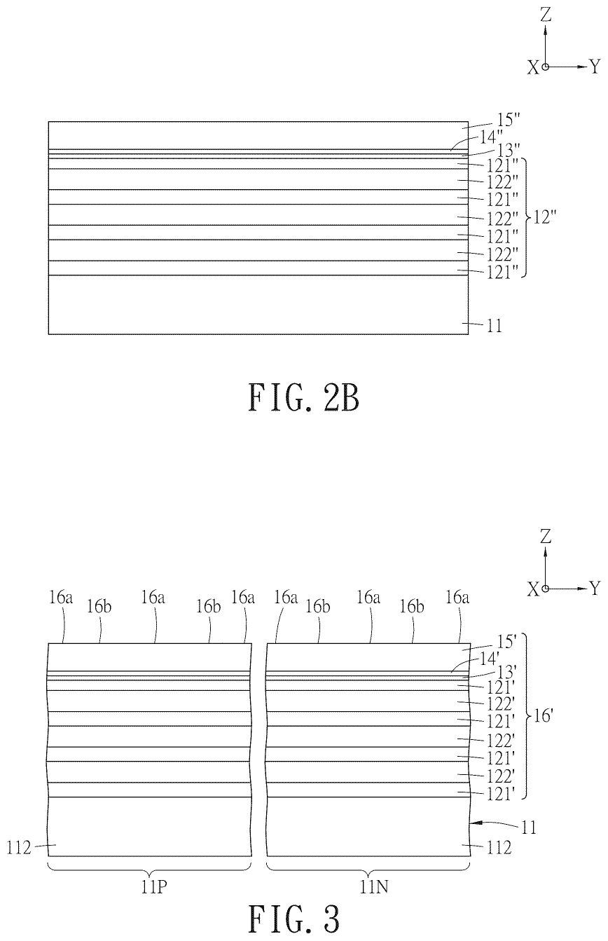

The present disclosure is directed to a semiconductor device and a method for manufacturing the same. FIGS. 1A and 1B are flow diagrams illustrating a method 100A for manufacturing a semiconductor device including, for example, a p-type metal-oxide-semiconductor FET (PMOSFET) 50P or an n-type metal-oxide-semiconductor FET (NMOSFET) 50N shown in FIG. 20 in accordance with some embodiments. FIGS. 2A to 19 illustrate schematic views of some intermediate stages of the method 100A. Some portions may be omitted in FIGS. 2A to 19 for the sake of brevity. Additional steps can be provided before, after or during the method 100A, and some of the steps described herein may be replaced by other steps or be eliminated.

Referring to FIG. 1A and the example illustrated in FIGS. 2A and 2B, the method 100A begins at step S01, where a semiconductor structure is formed. FIG. 2B illustrates a cross-sectional view taken along line I-I of FIG. 2A. The semiconductor structure includes a semiconductor substrate 11, a nanosheet stack 12″, a dummy silicon layer 13″, an oxide layer 14″, and a protective layer 15″.

The semiconductor substrate 11 may include, for example, but not limited to, an elemental semiconductor or a compound semiconductor. In some embodiments, the elemental semiconductor includes a single species of atoms, such as silicon or germanium in column XIV of the periodic table, and may be in a crystal form, a polycrystalline form, or an amorphous form. Other suitable elemental semiconductor materials are within the contemplated scope of the present disclosure. In some embodiments, the compound semiconductor includes two or more elements, and examples thereof may include, silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, and gallium indium arsenide phosphide. Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate 11 may include a multilayer compound semiconductor structure. In some embodiments, the semiconductor substrate 11 may be a semiconductor on insulator (SOI) (e.g., silicon germanium on insulator (SGOI)). The SOI substrate may be doped with a p-type dopant, for example, but not limited to, boron, aluminum, or gallium. Other suitable p-type dopant materials are within the contemplated scope of the present disclosure. Alternatively, the SOI substrate may be doped with an n-type dopant, for example, but not limited to, nitrogen, phosphorous, or arsenic. Other suitable n-type dopant materials are within the contemplated scope of the present disclosure. In some embodiments, the semiconductor substrate 11 has a (110) crystal plane. In some embodiments, the semiconductor substrate 11 is a (110) silicon substrate.

The nanosheet stack 12″ is disposed on the semiconductor substrate 11 in a Z direction normal to the semiconductor substrate 11. The nanosheet stack 12″ includes a plurality of sacrificial layers 121″ and a plurality of channel layers 122″ disposed to alternate with the sacrificial layers 121″ in the Z direction. In some embodiments, the nanosheet stack 12″ is a stack of semiconductor materials. In some embodiments, the sacrificial layers 121″ are made of a first semiconductor material, and the channel layers 122″ are made of a second semiconductor material that is different from the first semiconductor material, so that each layer of the channel layers 122″ has an etching selectivity (or an etching rate) different from that of each layer of the sacrificial layers 121″. In some embodiments, the first semiconductor material may be silicon germanium, and the second semiconductor material may be silicon, so that each layer of the sacrificial layers 121″ has an etching selectivity (or an etching rate) greater than that of each layer of the channel layers 122″. In some embodiments, the nanosheet stack 12″ may be formed on the semiconductor substrate 11 by a suitable deposition process (for example, but not limited to, chemical vapor deposition (CVD), atomic layer deposition (ALD), etc.), or a suitable epitaxial growth process (for example, but not limited to, molecular beam epitaxy (MBE), selective epitaxial growth (SEG) process, etc.). Other suitable processes for forming the nanosheet stack 12″ are within the contemplated scope of the present disclosure.

The dummy silicon layer 13″ is disposed on the nanosheet stack 12″ opposite to the semiconductor substrate 11. In some embodiments, the dummy silicon layer 13″ may be formed by a suitable epitaxial growth process (e.g., the SEG process). Other suitable processes for forming the dummy silicon layer 13″ are within the contemplated scope of the present disclosure.

The oxide layer 14″ is disposed on the dummy silicon layer 13″ opposite to the nanosheet stack 12″. In some embodiments, the oxide layer 14″ may be formed by a suitable deposition process, for example, but not limited to, CVD or ALD. Other suitable processes for forming the oxide layer 14″ are within the contemplated scope of the present disclosure.

The protective layer 15″ is disposed on the oxide layer 14″ opposite to the dummy silicon layer 13″. In some embodiments, the protective layer 15″ may include, for example, but not limited to, silicon nitride, silicon carbonitride, or a combination thereof. Other suitable materials for forming the protective layer 15″ are within the contemplated scope of the present disclosure. In some embodiments, the protective layer 15″ may be formed by a suitable deposition process, for example, but not limited to, CVD or ALD. Other suitable processes for forming the protective layer 15″ are within the contemplated scope of the present disclosure.

Referring to FIG. 1A and the example illustrated in FIG. 3, the method 100A then proceeds to step S02, where the semiconductor structure is patterned to form a plurality of fin structures 16′. One of the fin structures 16′ is shown in FIG. 3. Step S02 may be performed by a photolithography process, which includes an etching process. The etching process may be, for example, but not limited to, an anisotropic etching process. After this step, the semiconductor substrate 11 is formed into a lower portion (not shown) and a plurality of fin portions 112 that are disposed on the lower portion and that are spaced apart from one another in an X direction transverse to the Z direction; the sacrificial layers 121″ are formed into a plurality of sacrificial layer portions 121′; the channel layers 122″ are formed into a plurality of channel layer portions 122′; the dummy silicon layer 13″ is formed into a plurality of dummy silicon layer portions 13′; the oxide layer 14″ is formed into a plurality of oxide layer portions 14′; and the protective layer 15″ is formed into a plurality of protective layer portions 15′. The fin structures 16′ extend in a Y direction that is transverse to the Z direction and the X direction, and that is parallel to the semiconductor substrate 11. The fin structures 16′ are spaced apart from one another by trenches (not shown) in the X direction. Each of the fin structures 16′ is disposed on a corresponding one of the fin portions 112 of the semiconductor substrate 11, and includes corresponding ones of the sacrificial layer portions 121′, corresponding ones of the channel layer portions 122′ disposed to alternate with the corresponding ones of the sacrificial layer portions 121′ in the Z direction, a corresponding one of the dummy silicon layer portions 13', a corresponding one of the oxide layer portions 14′, and a corresponding one of the protective layer portions 15′. In some embodiments, an upper surface of each of the fin structures 16′ (i.e., an upper surface of each of the protective layer portions 15′) may have a plurality of covered regions 16a and a plurality of exposed regions 16b that are separated from one another in the Y direction. In some embodiments, the semiconductor substrate 11 may be divided into a p-type device region 11P and an n-type device region 11N for the PMOSFET 50P and the NMOSFET 50N (see FIG. 20) to be respectively formed thereon in subsequent steps.

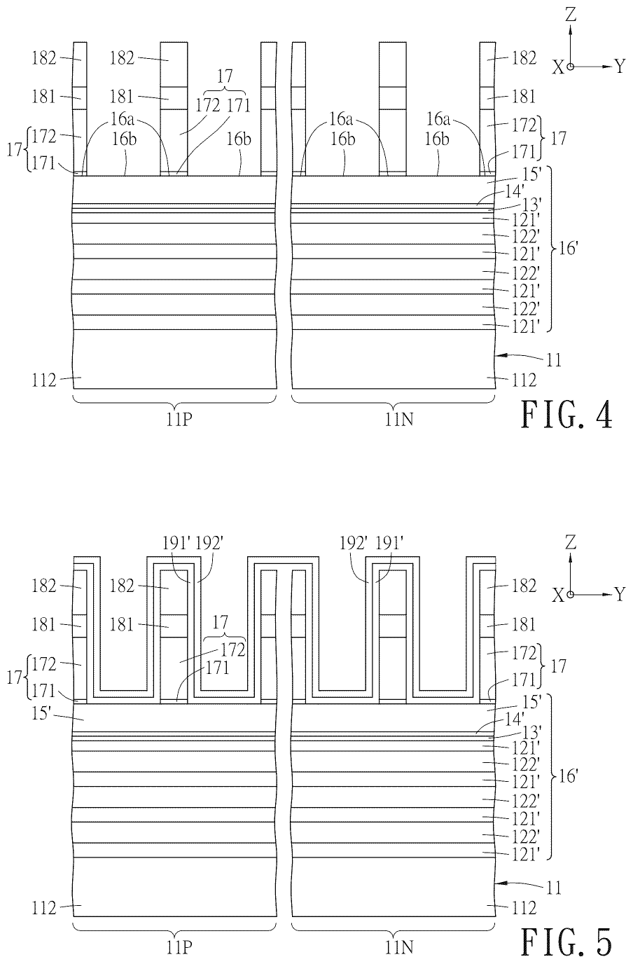

Referring to FIG. 1A and the example illustrated in FIG. 4, the method 100A then proceeds to step S03, where a plurality of isolation portions (not shown), a plurality of dummy poly gates 17, a plurality of mask portions 181, and a plurality of mask portions 182 are formed on the structure shown in FIG. 3. The dummy poly gates 17, the mask portions 181, and the mask portions 182 are formed on the isolation portions and over the fin structures 16', and are spaced apart from each other in the Y direction. Each of the dummy poly gates 17 includes a dummy gate dielectric 171 (i.e., a plurality of the dummy gate dielectrics 171 are formed after step S03) and a dummy gate electrode 172 (i.e., a plurality of the dummy gate electrodes 172 are formed after step S03). Step S03 includes sub-steps (i) to (v).

In sub-step (i), the isolation portions are formed on the lower portion of the semiconductor substrate 11. Each pair of the isolation portions is located at two opposite sides of a corresponding one of the fin portions 112 of the semiconductor substrate 11 so as to separate and isolate the fin structures 16′ from each other. The two opposite sides of the corresponding one of the fin portions 112 are opposite to each other in the X direction. In some embodiments, the isolation portions may be made of an oxide-based material (e.g., silicon oxide), a nitride-based material (e.g., silicon nitride), or a combination thereof. Other suitable materials for forming the isolation portions are within the contemplated scope of the present disclosure. In some embodiments, the isolation portions may be formed by a suitable deposition process, for example, but not limited to, CVD or physical vapor deposition (PVD). Other suitable processes for forming the isolation portions are within the contemplated scope of the present disclosure. In some embodiments, each of the isolation portions may be a portion of a shallow trench isolation (STI), a deep trench isolation (DTI), or other suitable isolation structures.

In sub-step (ii), a first dummy layer for forming the dummy gate dielectrics 171 is conformally formed on the structure obtained after sub-step (i) by a suitable deposition process, for example, but not limited to, CVD, ALD, or PVD. In some embodiments, the first dummy layer may be made of an oxide-based material (e.g., silicon oxide). Other suitable materials for forming the first dummy layer are within the contemplated scope of the present disclosure.

In sub-step (iii), a second dummy layer for forming the dummy gate electrodes 172 is formed on the structure obtained after sub-step (ii), followed by conducting a planarization process to remove an excess portion of the second dummy layer. In some embodiments, the second dummy layer may include polysilicon. Other suitable materials for forming the second dummy layer are within the contemplated scope of the present disclosure. In some embodiments, the second dummy layer may be formed by a suitable deposition process, for example, but not limited to, CVD, ALD, or PVD. In some embodiments, the planarization process may be a chemical mechanical polishing (CMP) or other suitable planarization processes.

In sub-step (iv), two mask material layers for respectively forming the mask portions 181, 182 are formed on the structure obtained after sub-step (iii). In some embodiments, the mask material layer for forming the mask portions 181 may include silicon nitride, and the mask material layer for forming the mask portions 182 may include oxide-based material (e.g., silicon oxide). Other suitable materials for forming the mask material layers are within the contemplated scope of the present disclosure.

In sub-step (v), the structure obtained after sub-step (iv) is patterned by a photolithography process, which includes an etching process, thereby obtaining the dummy poly gates 17, the mask portions 181, and the mask portions 182.

The dummy gate dielectric 171 of each of the dummy poly gates 17 is disposed on a corresponding one of the covered regions 16a of each of the fin structures 16′. The dummy gate electrode 172 is disposed on the dummy gate dielectric 171. Each of the mask portions 181 is disposed on a corresponding one of the dummy poly gates 17. Each of the mask portions 182 is disposed on a corresponding one of the mask portions 181 opposite to a corresponding one of the dummy poly gates 17.

Referring to FIG. 1A and the example illustrated in FIG. 5, the method 100A then proceeds to step S04, where a spacer material layer 191′ and a spacer material layer 192′ are sequentially and conformally formed on the structure shown in FIG. 4. In some embodiments, each of the spacer material layers 191′, 192′ may include, for example, but not limited to, silicon oxide, silicon nitride, silicon oxynitride, silicon carbonitride, silicon oxycarbonitride, or low-dielectric constant (k) materials. Other suitable materials for forming the spacer material layers 191′, 192′ are within the contemplated scope of the present disclosure. In some embodiments, the spacer material layers 191', 192′ may be made of different materials. In some embodiments, each of the spacer material layers 191′, 192′ may be formed by a suitable deposition process, for example, but not limited to, CVD or ALD. Other suitable deposition processes for forming the spacer material layers 191′, 192′ are within the contemplated scope of the present disclosure. In some embodiments, the spacer material layer 191′ is formed to cover two opposite sides of each of the dummy poly gates 17, two opposite sides of each of the mask portions 181, two opposite sides and an upper surface of each of the mask portions 182, and the exposed regions 16b of the fin structures 16′ (see FIG. 4), and the spacer material layer 192′ is formed to cover the spacer material layer 191′.

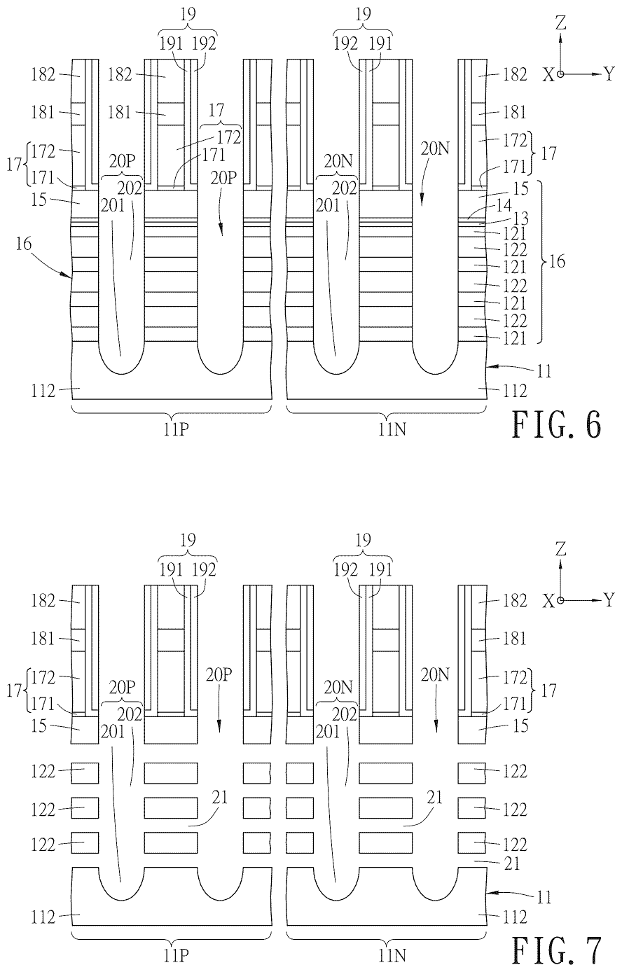

Referring to FIG. 1A and the example illustrated in FIG. 6, the method 100A then proceeds to step S05, where an anisotropic dry etching process is performed on the structure shown in FIG. 5, so as to form a plurality of source/drain trenches 20P and a plurality of source/drain trenches 20N. The source/drain trenches 20P are located in the p-type device region 11P and the source/drain trenches 20N are located in the n-type device region 11N. Step S05 may be performed by removing portions of the spacer material layers 191′, 192′, which are respectively formed on the exposed regions 16b of the fin structures 16′ and the upper surface of each of the mask portions 182, followed by removing portions of the fin structures 16′ through the exposed regions 16b of the fin structures 16′ (see FIG. 4). Each of remaining portions of the spacer material layer 191′ (see FIG. 5), and a corresponding one of remaining portions of the spacer material layer 192′ (see FIG. 5) may cooperatively serve as a gate spacer 19 (i.e., a plurality of the gate spacers 19 are formed after this step). In some embodiments, each of the gate spacers 19 includes an inner portion 191, which is one of the remaining portions of the spacer material layer 191′, and an outer portion 192, which is one of the remaining portions of the spacer material layer 192′. In some embodiments, each pair of the gate spacers 19 is respectively formed at two opposite sides of a corresponding one of the dummy poly gates 17, two opposite sides of a corresponding one of the mask portions 181, and two opposite sides of a corresponding one of the mask portions 182. In some embodiments, the source/drain trenches 20P, 20N are spaced apart from one another in the Y direction. After this step, the fin structures 16′ (see FIG. 5) are formed into a plurality of stack portions 16. Each of the stack portions 16 includes a plurality of sacrificial features 121 (formed from the sacrificial layer portions 121′ (see FIG. 5)), a plurality of channel features 122 (formed from the channel layer portions 122′ (see FIG. 5)), a corresponding one of a plurality of dummy silicon features 13 (formed from the dummy silicon layer portions 13′ (see FIG. 5)), a corresponding one of a plurality of oxide features 14 (formed from the oxide layer portions 14′ (see FIG. 5)), and a corresponding one of a plurality of protective features 15 (formed from the protective layer portions 15′ (see FIG. 5)). In some embodiments, each of the source/drain trenches 20P, 20N includes a lower trench portion 201 and an upper trench portion 202 disposed above and in spatial communication with the lower trench portion 201.

Referring to FIG. 1A and the example illustrated in FIG. 7, the method 100A then proceeds to step S06, where the sacrificial features 121, the dummy silicon features 13, and the oxide features 14 are removed, so as to form a plurality of spaces 21. Step S06 may be performed by an isotropic etching process, for example, but not limited to, a wet etching process or other suitable etching processes. Each of uppermost ones of the spaces 21 is located between a corresponding one of the protective features 15 and a corresponding one of the channel features 122, each of lowermost ones of the spaces 21 is located between a corresponding one of the channel features 122 and a corresponding one of the fin portions 112 of the semiconductor substrate 11, and each of remaining ones of the spaces 21 is located between corresponding two adjacent ones of the channel features 122. It is noted that the isolation portions (as described in step S03) may be slightly removed after this step.

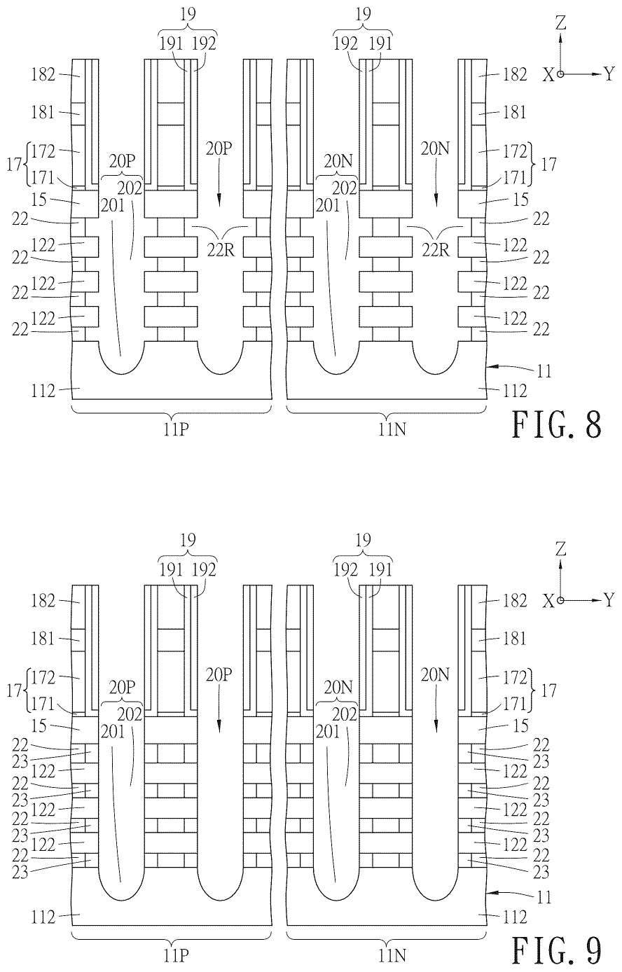

Referring to FIG. 1A and the examples illustrated in FIG. 8, the method 100A then proceeds to step S07, where a plurality of interposers 22 are formed. The interposers 22 will be removed in a subsequent step, and thus may be referred to as sacrificial features. Step S07 may include sub-steps (i) and (ii).

In sub-step (i), an oxide-based material layer (e.g., a silicon oxide layer) for forming the interposers 22 is formed on the structure shown in FIG. 7 by a suitable deposition process, for example, but not limited to, CVD or ALD. Other suitable deposition processes for forming the oxide-based material layer are within the contemplated scope of the present disclosure.

In sub-step (ii), an isotropic etching process is performed to remove an excess portion of the oxide-based material layer, so as to obtain the interposers 22. Each of uppermost ones of the interposers 22 is located between a corresponding one of the protective features 15 and a corresponding one of the channel features 122, each of lowermost ones of the interposers 22 is located between a corresponding one of the channel features 122 and a corresponding one of the fin portions 112 of the semiconductor substrate 11, and each of remaining ones of the interposers 22 is located between corresponding two adjacent ones of the channel features 122. After this sub-step, a plurality of lateral recesses 22R are formed. In some embodiments, the lateral recesses 22R may be not formed.

Referring to FIG. 1A and the example illustrated in FIG. 9, the method 100A then proceeds to step S08, where a plurality of inner spacers 23 are formed. Step S08 includes sub-step (i) of forming a spacer material layer (not shown) on the structure shown in FIG. 8 to fill the lateral recesses 22R by a suitable deposition process, for example, but not limited to, CVD, ALD, or other suitable deposition processes, and sub-step (ii) of removing an excess portion of the spacer material layer by a suitable etching process, for example, but not limited to, a dry etching process, a wet etching process, or a combination thereof, thereby obtaining the inner spacers 23. In some embodiments, the spacer material layer for forming the inner spacers 23 may include, for example, but not limited to, silicon oxide, silicon nitride, silicon oxynitride, silicon carbonitride, silicon oxycarbonitride, silicon oxycarbide, silicon carbide, aluminum oxide, hafnium oxide, zirconium oxide, or combinations thereof. Other suitable materials for forming the spacer material layer are within the contemplated scope of the present disclosure. After sub-step (ii), remaining portions of the spacer material layer may be referred to as the inner spacers 23. In some embodiments, each pair of the inner spacers 23 laterally covers two opposite sides of a corresponding one of the interposers 22. In some embodiments, in which the the lateral recesses 22R shown in FIG. 8 are not formed, the inner spacers 23 may be not formed (i.e., step S08 may be omitted).

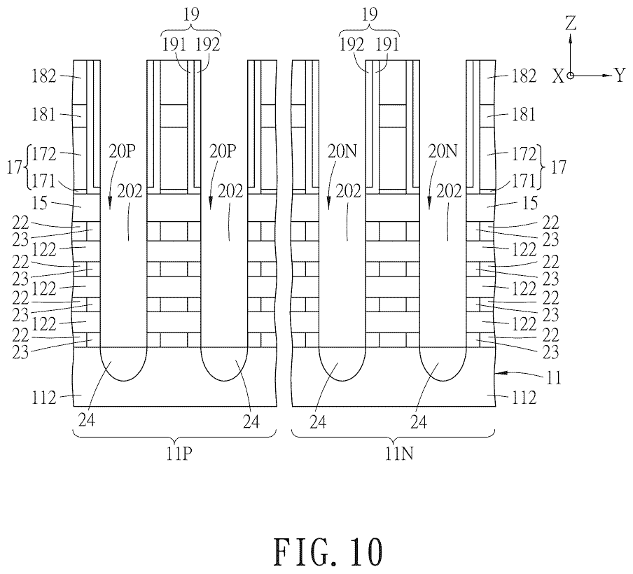

Referring to FIG. 1A and the example illustrated in FIG. 10, the method 100A then proceeds to step S09, where a plurality of first layers 24 are formed in the lower trench portions 201 of the source/drain trenches 20P, 20N (see FIG. 9), respectively. In some embodiments, the first layers 24 may be made of silicon. In some embodiments, the first layers 24 may be formed by a suitable epitaxial growth process, for example, but not limited to, the SEG process.

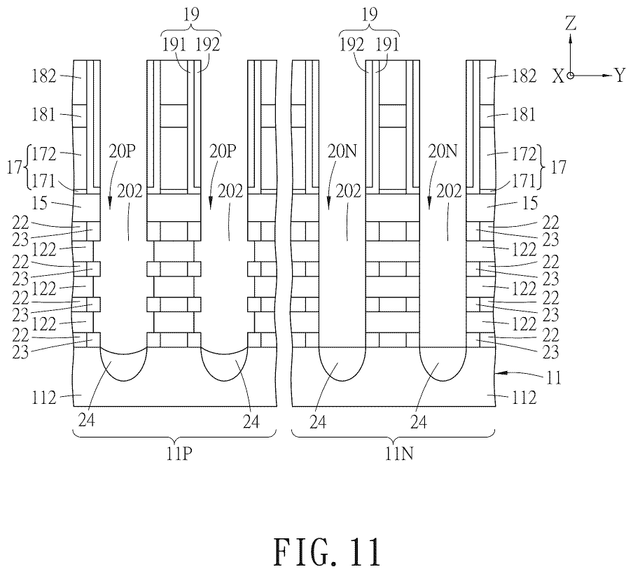

Referring to FIG. 1A and the example illustrated in FIG. 11, the method 100A then proceeds to step S10, where an isotropic etching process is performed on the structure in the p-type device region 11P shown in FIG. 10, so as to recess the channel features 122 and the first layers 24 in the p-type device region 11P. In this step, the channel features 122 are laterally recessed and an upper surface of each of the first layers 24 is recessed. In some embodiments, recessing the channel features 122 and the first layers 24 is conducive to improving electrical performance (e.g., DC performance) of the PMOSFET 50P (see FIG. 20). In some embodiments, step S10 may be omitted.

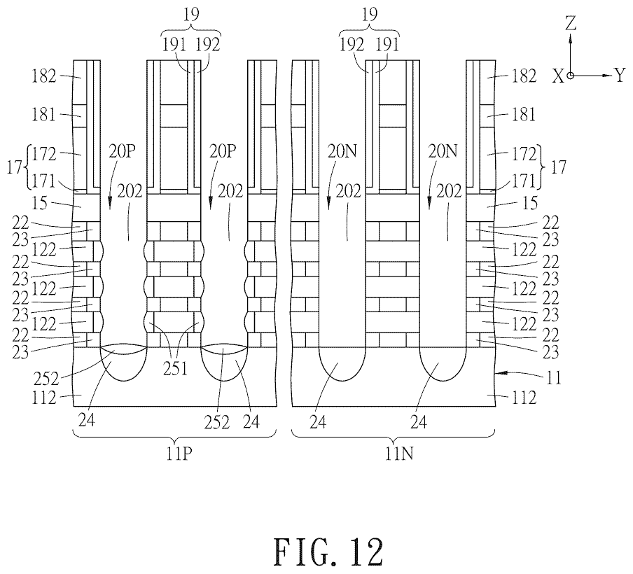

Referring to FIG. 1B and the example illustrated in FIG. 12, the method 100A then proceeds to step S11, where a plurality of second layers 251, 252 are formed in the p-type device region 11P. Each of the second layers 251 is laterally disposed on a side surface of a corresponding one of the recessed channel features 122, and each of the second layers 252 is disposed on a recessed upper surface of a corresponding one of the first layers 24. In some embodiments, each of the second layers 251, 252 is made of silicon doped with boron. In some embodiments, the second layers 251, 252 may be formed by a suitable epitaxial growth process, for example, but not limited to, the SEG process. Each of the second layers 251, 252 may be used as a covering layer to prevent a corresponding one of the recessed channel features 122 and a corresponding one of the first layers 24 from being damaged in subsequent steps (e.g., step S18). In some embodiments, the second layers 251, 252 may be referred to as silicon-based layers.

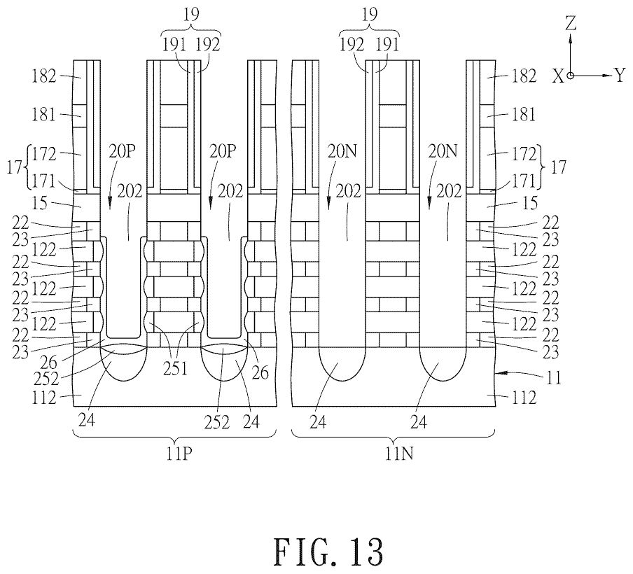

Referring to FIG. 1B and the example illustrated in FIG. 13, the method 100A then proceeds to step S12, where a plurality of third layers 26 are formed. Each of the third layers 26 may be referred to as a base layer. Each of the third layers 26 is conformally formed in the upper trench portion 202 of a corresponding one of the source/drain trenches 20P, and is formed on corresponding ones of the inner spacers 23 and corresponding ones of the second layers 251, 252. In some embodiments, each of the third layers 26 is made of silicon germanium having a germanium concentration that ranges from about 10% to about 20%. If the germanium concentration in each of the third layers 26 is lower than 10%, the electrical performance of the PMOSFET 50P (see FIG. 20) may be adversely affected. If the germanium concentration in each of the third layers 26 is greater than 20%, difficulty in forming the each of the third layers 26 may increase.

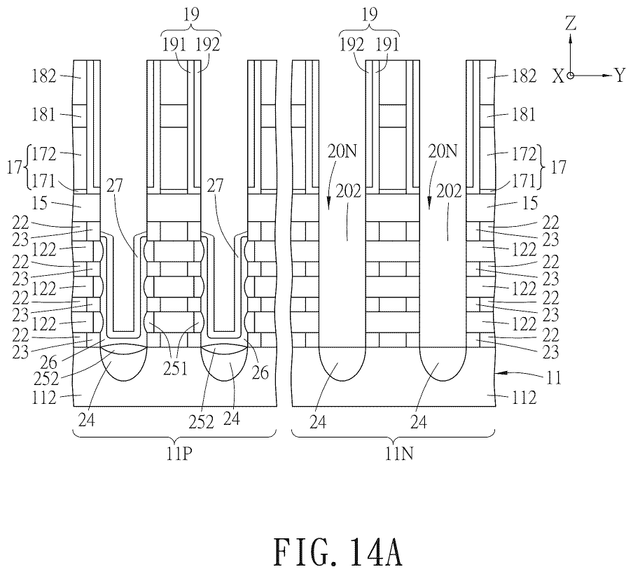

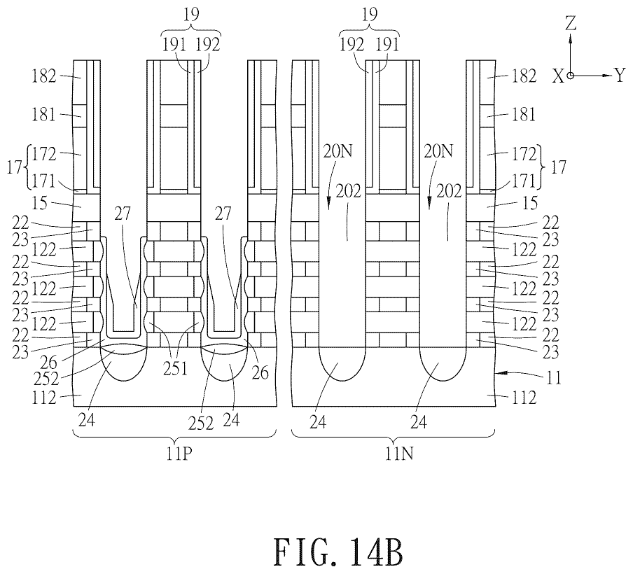

Referring to FIG. 1B and the example illustrated in FIGS. 14A and 14B, the method 100A then proceeds to step S13, where a plurality of fourth layers 27 are formed, followed by removing an upper part of each of two side portions of each of the fourth layers 27. Step S13 includes sub-steps (i) and (ii).

In sub-step (i), as shown in FIG. 14A, each of the fourth layers 27 is conformally formed on a corresponding one of the third layers 26 in the upper trench portion 202 of a corresponding one of the source/drain trenches 20P. Each of the fourth layers 27 may be referred to as a first intermediate layer. In some embodiments, each of the fourth layers 27 is made of silicon germanium having a germanium concentration that ranges from about 40% to about 65%. If the germanium concentration in each of the fourth layers 27 is lower than 40%, the electrical performance of the PMOSFET 50P (see FIG. 20) may be adversely affected. If the germanium concentration in each of the fourth layers 27 is greater than 65%, difficulty in forming the each of the fourth layers 27 may increase. In some embodiments, the fourth layers 27 are formed by a suitable epitaxial growth process, for example, but not limited to, the SEG process.

In sub-step (ii), as shown in FIG. 14B, an etchant is introduced to etch away the upper part of each of the side portions of the each of the fourth layers 27. In some embodiments, an etchant may include, for example, but not limited to, hydrogen chloride, hydrogen radicals, chlorine radicals, fluorine radicals, or combinations thereof. Other suitable etchants are within the contemplated scope of the present disclosure.

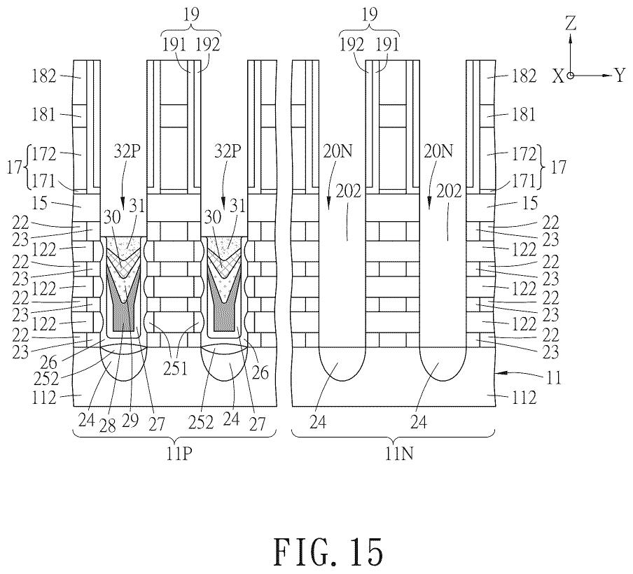

Referring to FIG. 1B and the example illustrated in FIG. 15, the method 100A then proceeds to step S14, where a plurality of fifth layers 28, a plurality of sixth layers 29, a plurality of seventh layers 30, and a plurality of eighth layers 31 are sequentially formed to fill the source/drain trenches 20P. Each of the fifth layers 28 may be referred to as a second intermediate layer, each of the sixth layers 29 may be referred to as a third intermediate layer, each of the seventh layers 30 may be referred to as a fourth intermediate layer, and each of the eighth layers 31 may be referred to as an upper layer. Sequential formation of the fifth layers 28, the sixth layers 29, and the seventh layers 30 may be conducted by repeating a sub-step similar to step S13, and the eighth layers 31 are then formed on the seventh layers 30 by a suitable epitaxial growth process, for example, but not limited to, the SEG process, so that these layers fill the source/drain trenches 20P. In some embodiments, an etching process may be conducted to remove an excess portion of each of the eighth layers 31.

In some embodiments, a material (silicon germanium) for forming each of the fifth layers 28, the sixth layers 29, the seventh layers 30, and the eighth layers 31 is similar to that for forming the fourth layers 27 except that the germanium concentration of the material is different. In some embodiments, the germanium concentration in each of the fifth layers 28, the sixth layers 29, the seventh layers 30, and the eighth layers 31 may range from about 40% to about 65%. If the germanium concentration in each of the fifth layers 28, the sixth layers 29, the seventh layers 30, and the eighth layers 31 is lower than 40%, the electrical performance of the PMOSFET 50P (see FIG. 20) may be adversely affected. If the germanium concentration in each of the fifth layers 28, the sixth layers 29, the seventh layers 30, and the eighth layers 31 is greater than 65%, difficulty in forming the each of the fifth layers 28, the sixth layers 29, the seventh layers 30, and the eighth layers 31 may increase. In some embodiments, the germanium concentration in the eighth layers 31 is greater than that in the seventh layers 30, the germanium concentration in the seventh layers 30 is greater than that in the sixth layers 29, the germanium concentration in the sixth layers 29 is greater than that in the fifth layers 28, and the germanium concentration in the fifth layers 28 is greater than that in the fourth layers 27. In some embodiments, a p-type dopant (e.g., boron or other suitable p-type dopants) may be doped in the material (silicon germanium) during formation of the third layers 26, the fourth layers 27, the fifth layers 28, the sixth layers 29, the seventh layers 30, and/or the eighth layers 31. In some alternative embodiments, the p-type dopant may be doped in the third layers 26, the fourth layers 27, the fifth layers 28, the sixth layers 29, the seventh layers 30, and/or the eighth layers 31 after the formation thereof.

In some embodiments, each of the third layers 26, a corresponding one of the fourth layers 27, a corresponding one of the fifth layers 28, a corresponding one of the sixth layers 29, a corresponding one of the seventh layers 30, and a corresponding one of the eighth layers 31 are collectively referred to as a source/drain portion 32P (i.e., a plurality of the source/drain portions 32P are formed after step S14). In some embodiments, each of the source/drain portions 32P may have a p-type conductivity, so as to function as a source/drain of the PMOSFET 50P (see FIG. 20). It is noted that there is no limitation on a number of layers in each of the source/drain portions 32P.

In some embodiments, a mask (not shown) is used to cover the structure in the n-type device region 11N during steps S10 to S14. In some embodiments, steps S12 to S14 are collectively referred to as a cyclic deposition etching (CDE) process. Bottom-up growth of a plurality of layers (for example, but not limited to, the fourth layers 27, the fifth layers 28, the sixth layers 29, the seventh layers 30, and the eighth layers 31) in each of the source/drain portions 32P formed on the semiconductor substrate 11 (the (110) silicon substrate) can be achieved by the CDE process, which is conducive to improving the electrical performance (e.g., the DC performance) of the PMOSFET 50P (see FIG. 20). In addition, a gradual increase of the germanium concentration in the third layers 26 to the eighth layers 31 is also beneficial for improving the electrical performance of the PMOSFET 50P.

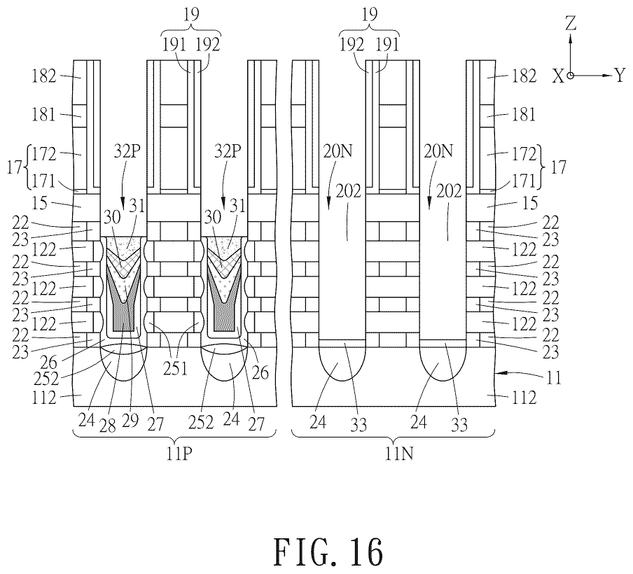

Referring to FIG. 1B and the example illustrated in FIG. 16, the method 100A then proceeds to step S15, where a plurality of insulator layers 33 are respectively formed on the first layers 24 in the source/drain trenches 20N. The mask covering the structure in the n-type device region 11N is removed and another mask is formed to cover the structure in the p-type device region 11P shown in FIG. 16, and step S15 is then performed. Step S15 may include sub-step (i) of depositing a dielectric material layer for forming the insulator layers 33 on the structure shown in FIG. 15 by a suitable deposition process, for example, but not limited to, CVD, ALD, or other suitable deposition processes; and sub-step (ii) of removing excess portions of the dielectric material layer by a suitable etching process, for example, but not limited to, wet etching, dry etching, other suitable etching processes, or combinations thereof, such that remaining portions of the dielectric material layer serve as the insulator layers 33 which are respectively formed on the first layers 24 in the source/drain trenches 20N. In some embodiments, the dielectric material layer may be made of silicon nitride. Other suitable materials for forming the dielectric material layer are within the contemplated scope of the present disclosure. In some embodiments, the insulator layers 33 may be referred to as flexible bottom insulators (FBIs), and may be used to shut-off a leakage path in the NMOSFET 50N (see FIG. 20).

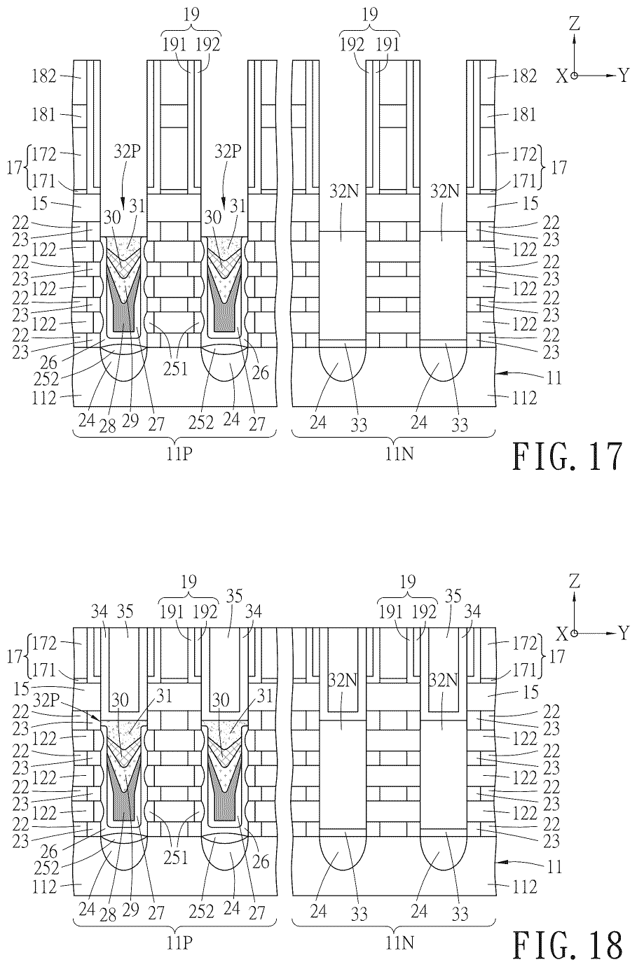

Referring to FIG. 1B and the example illustrated in FIG. 17, the method 100A then proceeds to step S16, where a plurality of source/drain portions 32N are respectively formed on the insulator layers 33 such that the source/drain portions 32N respectively fill the upper portions 202 of the source/drain trenches 20N (see FIG. 16). In some embodiments, the source/drain portions 32N may include, for example, but not limited to, silicon phosphide or silicon arsenic. In some embodiments, the source/drain portions 32N may be formed by a suitable epitaxial growth process, for example, but not limited to, the SEG process. In some embodiments, each of the source/drain portions 32N may have an n-type conductivity, so as to function as a source/drain of the NMOSFET 50N (see FIG. 20). In some embodiments, the source/drain portions 32N may be formed before the source/drain portions 32P are formed.

Referring to FIG. 1B and the example illustrated in FIG. 18, the method 100A then proceeds to step S17, where a plurality of contact etch stop portions 34 and a plurality of inter-layer dielectric (ILD) portions 35 are respectively formed on the source/drain portions 32P, 32N. Step S17 includes sub-steps (i) to (iii).

In sub-step (i), a contact etch stop layer (not shown) for forming the contact etch stop portions 34 is conformally formed on the structure shown in FIG. 17. In some embodiments, the contact etch stop layer may include, for example, but not limited to, silicon nitride, carbon-doped silicon nitride, or a combination thereof. Other suitable materials for forming the contact etch stop layer are within the contemplated scope of the present disclosure. In some embodiments, the contact etch stop layer may be formed by a suitable deposition process, for example, but not limited to, CVD. Other suitable deposition processes for forming the contact etch stop layer are within the contemplated scope of the present disclosure.

In sub-step (ii), a dielectric material layer (not shown) for forming the ILD portions 35 is formed on the structure obtained after sub-step (i). In some embodiments, the dielectric material layer may include, for example, but not limited to, silicon oxide, silicon nitride, silicon oxynitride, other low-k dielectric materials, or combinations thereof. Other suitable materials for forming the dielectric material layer are within the contemplated scope of the present disclosure. In some embodiments, the dielectric material layer may be formed by a suitable deposition process, for example, but not limited to, CVD. Other suitable processes for forming the dielectric material layer are within the contemplated scope of the present disclosure.

In sub-step (iii), an excess portion of the dielectric material layer, an excess portion of the contact etch stop layer, the mask portions 182, the mask portions 181, and portions of the gate spacers 19 are removed by a suitable planarization process until an upper surface of each of the dummy gate electrodes 172 is exposed, thereby obtaining the contact etch stop portions 34 (i.e., remaining portions of the contact etch stop layer) and the ILD portions 35 (i.e., remaining portions of the dielectric material layer). In some embodiments, the planarization process may be, for example, but not limited to, CMP or other suitable planarization processes. In some embodiments, in this sub-step, a portion of the each of the dummy gate electrodes 172 may be removed.

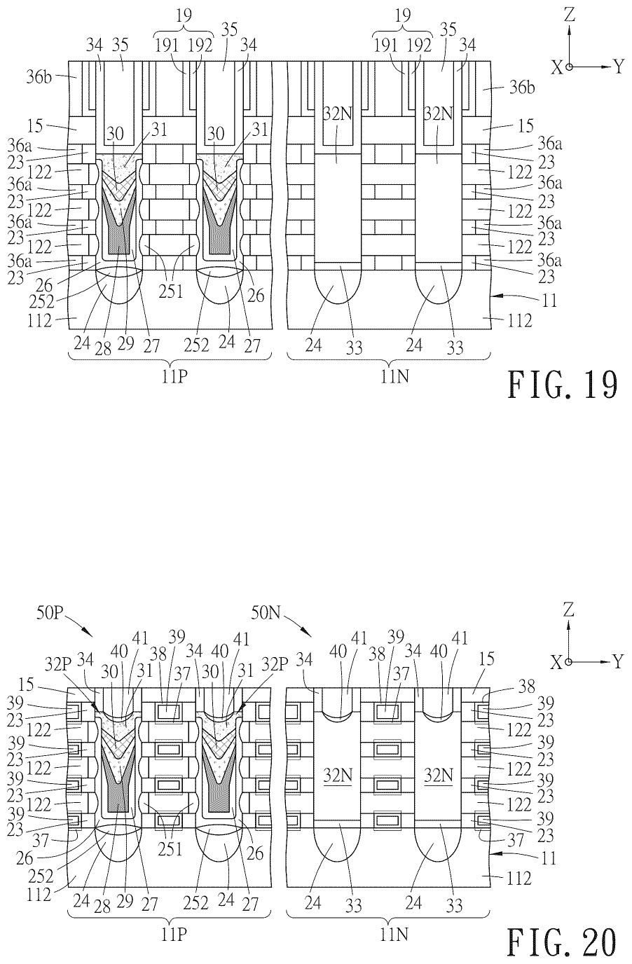

Referring to FIG. 1B and the example illustrated in FIG. 19, the method 100A then proceeds to step S18, where the dummy poly gates 17 and the interposers 22 are removed, so as to form a plurality of cavities 36a, 36b. Step S18 may be performed by two or more etching processes. In some embodiments, the etching process for removing the dummy poly gates 17 may be, a wet etching process, a dry etching process, or a combination thereof. In some embodiments, the etching process for removing the interposers 22 may be an isotropic dry etching process, an isotropic wet etching process, or a combination thereof. Other suitable etching processes for removing the dummy poly gates 17 and the interposers 22 are within the contemplated scope of the present disclosure. The cavities 36a are defined by the inner spacers 23 and the channel features 122, and the cavities 36b are defined by the gate spacers 19 and the protective features 15. In some embodiments, in this step, each of the channel features 122 may be slightly etched.

Referring to FIG. 1B and the example illustrated in FIG. 20, the method 100A then proceeds to step S19, where a plurality of interfacial features 37, a plurality of gate dielectrics 38, a plurality of gate electrodes 39, a plurality of silicide features 40, and a plurality of conductive features 41 are sequentially formed. Step S19 includes sub-steps (i) to (v).

In sub-step (i), the interfacial features 37 are formed on etched portions of the channel features 122 of the structure shown in FIG. 20, respectively. In some embodiments, the interfacial features 37 may include, for example, but not limited to, silicon oxide. Other suitable materials for forming the interfacial features 37 are within the contemplated scope of the present disclosure. In some embodiments, the interfacial features 37 may be formed by a suitable process, for example, but not limited to, wet chemical process, ALD, or thermal oxidation. Other suitable processes for forming the interfacial features 37 are within the contemplated scope of the present disclosure. Each of the interfacial features 37 surrounds a corresponding one of the channel features 122 and is covered by a corresponding one of the gate dielectrics 38.

In sub-step (ii), a gate dielectric layer (not shown) for forming the gate dielectrics 38 is formed in the cavities 36a, 36b. In some embodiments, the gate dielectric layer may include, for example, but not limited to, silicon oxide, silicon nitride, silicon oxynitride, a suitable high-k material (e.g., hafnium oxide, zirconium oxide, zirconium aluminum oxide, hafnium aluminum oxide, hafnium silicon oxide, aluminum oxide, etc.), or combinations thereof. In some embodiments, the gate dielectric layer may be formed by a suitable deposition process, for example, but not limited to, CVD or ALD. Other suitable processes for forming the gate dielectric layer are within the contemplated scope of the present disclosure.

In sub-step (iii), a gate electrode layer (not shown) for forming the gate electrodes 39 is formed to fill the cavities 36a, 36b. In some embodiments, the gate electrode layer may include, for example, but not limited to, aluminum, copper, tungsten, cobalt, ruthenium, titanium, tantalum, molybdenum, nickel, platinum, titanium nitride, tantalum nitride, or combinations thereof. Other suitable materials for forming the gate electrode layer are within the contemplated scope of the present disclosure. In some embodiments, the gate electrode layer may be formed by a suitable deposition process, for example, but not limited to, CVD. Other suitable deposition processes for forming the gate electrode layer are within the contemplated scope of the present disclosure.

In sub-step (iv), a planarization process (e.g., CMP or other suitable planarization processes) is performed to remove an excess portion of the gate dielectric layer, an excess portion of the gate electrode layer, the gate spacers 19, upper parts of the contact etch stop portions 34, and upper parts of the ILD portions 35 until the protective features 15 are exposed, thereby obtaining the gate dielectrics 38 and the gate electrodes 39. In some embodiments, each of the gate dielectrics 38 and a corresponding one of the gate electrodes 39 may be collectively referred to as a metal gate (i.e., a plurality of the metal gates are formed in this sub-step), which is configured to surround corresponding ones of the channel features 122.

In sub-step (v), the silicide features 40 and the conductive features 41 are sequentially formed on corresponding ones of the source/drain portions 32P, 32N. In some embodiments, each of the silicide features 40 may include, for example, but not limited to, titanium silicide. In some embodiments, each of the conductive features 41 may include, for example, but not limited to, cobalt. In some embodiments, the silicide features 40 and the conductive features 41 may be formed by conducting a photolithography process to form a plurality of through holes (not shown) which respectively penetrate corresponding ones of the ILD portions 35 and the contact etch stop portions 34, followed by sequentially depositing respective materials for the silicide features 40 and the conductive features 41 such that the respective materials fill the through holes, and then conducting a planarization process (for example, but not limited to, CMP or other suitable planarization processes) to remove excess of the material for the conductive features 41 over the protective features 15.

After step S19, the PMOSFET 50P and the NMOSFET 50N are obtained. In some embodiments, in the PMOSFET 50P, each of the fourth layers 27, the fifth layers 28, the sixth layers 29, the seventh layers 30, and the eighth layers 31 includes a bottom portion and two side portions that extend from the bottom portion and that are spaced apart from each other. A thickness of each of the two side portions of the each of the fourth layers 27, the fifth layers 28, the sixth layers 29, the seventh layers 30, and the eighth layers 31 decreases in an upward direction from the semiconductor substrate 11.

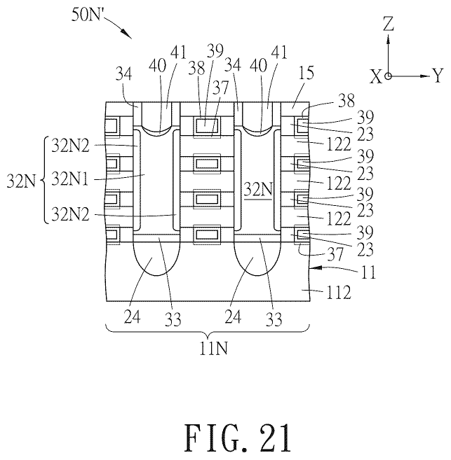

FIG. 21 illustrates a NMOSFET 50N′ in accordance with some embodiments. The NMOSFET 50N′ has a configuration similar to that of the NMOSFET 50N, except that, in the NMOSFET 50N′, each of the source/drain portions 32N is divided into a main part 32N1 and two side parts 32N2 respectively disposed at two opposite sides of the main part 32N1. In some embodiments, the main part 32N1 and the side parts 32N2 are made of different materials. In some embodiments, each of the side parts 32N2 is disposed among the main part 32N1 and corresponding ones of the channel features 122 and the inner spacers 23. In some embodiments, the main part 32N1 is made of silicon phosphide, and the side parts 32N2 are made of silicon arsenic. The side parts 32N2 may be used to prevent atoms of the source/drain portion 32N from diffusing into the channel features 122.

In this disclosure, a semiconductor device including a p-type metal-oxide-semiconductor FET (PMOSFET) is formed on a (110) silicon substrate, and bottom-up growth of a source/drain portion, which may function as a source/drain of the PMOSFET, can be achieved through a cyclic deposition etch (CDE) process. Therefore, electrical performance (e.g., direct current performance) of the semiconductor device of this disclosure can be improved. During the CDE process, each layer of the source/drain portion is formed by a suitable epitaxial growth process (e.g., selective epitaxial growth (SEG)), followed by removing an upper portion of the each layer using a suitable etchant.

In accordance with some embodiments of the present disclosure, a method for manufacturing a semiconductor device includes: forming a stack structure on a substrate, the stack structure including a plurality of sacrificial layer portions and a plurality of channel layer portions which are alternately stacked; forming a trench that penetrates the stack structure; forming a base layer in the trench; forming an intermediate layer on the base layer and in the trench, the intermediate layer including a bottom portion and two side portions that extend from the bottom portion and that are spaced apart from each other, each of the two side portions including an upper part and a lower part interconnected to the upper part and the bottom portion; removing the upper part of each of the two side portions of the intermediate layer; and forming an upper layer over the intermediate layer.

In accordance with some embodiments of the present disclosure, the substrate has a (110) crystal plane.

In accordance with some embodiments of the present disclosure, the base layer is made of a semiconductor material including silicon germanium which contains germanium in a first germanium concentration ranging from 10% to 20%.

In accordance with some embodiments of the present disclosure, the intermediate layer is made of a semiconductor material including silicon germanium which contains germanium in a second concentration ranging from 40% to 65%.

In accordance with some embodiments of the present disclosure, the upper layer is made of a semiconductor material including silicon germanium which contains germanium in a third concentration ranging from 40% to 65%, wherein the third concentration is greater than the second concentration.

In accordance with some embodiments of the present disclosure, removal of the upper part of the two side portions of the intermediate layer is performed using an etchant that includes hydrogen chloride, hydrogen radicals, chlorine radicals, fluorine radicals, or combinations thereof.

In accordance with some embodiments of the present disclosure, each of the plurality of sacrificial layer portions includes silicon germanium.

In accordance with some embodiments of the present disclosure, the plurality of sacrificial layer portions are formed into a plurality of sacrificial features after formation of the trench. The method for a semiconductor device further includes, before formation of the base layer, replacing the plurality of sacrificial features with a plurality of interposers, respectively.

In accordance with some embodiments of the present disclosure, a method for manufacturing a semiconductor device includes: forming two stack portions on a substrate, each of the stack portions including a plurality of sacrificial features and a plurality of channel features which are alternately stacked; forming a base layer between the two stack portions, the base layer being formed on a side surface of each of the two stack portions and an upper surface of the semiconductor substrate; forming a first intermediate layer on the base layer, the first intermediate layer including a bottom portion and two side portions that extend from the bottom portion and that are spaced apart from each other, each of the two side portions including an upper part and a lower part interconnected to the upper part and the bottom portion; removing the upper part of each of the two side portions of the first intermediate layer; and forming an upper layer over the first intermediate layer.

In accordance with some embodiments of the present disclosure, each of the plurality of sacrificial features includes silicon germanium.

In accordance with some embodiments of the present disclosure, the method for manufacturing the semiconductor device further includes, before formation of the base layer, replacing the plurality of sacrificial features with a plurality of interposers, respectively.

In accordance with some embodiments of the present disclosure, the method for manufacturing the semiconductor device further includes, after formation of the first intermediate layer and before formation of the upper layer, forming a second intermediate layer on the lower part of the each of the two side portions of the first intermediate layer, the second intermediate layer including a bottom portion and two side portions that extend from the bottom portion of the second intermediate layer and that are spaced apart from each other, each of the two side portions of the second intermediate layer including an upper part and a lower part interconnected to the upper part and the bottom portion of the second intermediate layer; and removing the upper part of each of the two side portions of the second intermediate layer. The upper layer is formed over the lower part of the each of the two side portions and the bottom portion of the second intermediate layer.

In accordance with some embodiments of the present disclosure, each of the base layer, the first intermediate layer, the second intermediate layer, and the upper layer is made of a semiconductor material including silicon germanium which contains germanium in a concentration.

In accordance with some embodiments of the present disclosure, the concentration of germanium in the base layer is lower than the concentration of germanium in the first intermediate layer, the concentration of germanium in the first intermediate layer is lower than the concentration of germanium in the second intermediate layer, and the concentration of germanium in the second intermediate layer is lower than the concentration of germanium in the upper layer.

In accordance with some embodiments of the present disclosure, a semiconductor device includes a substrate, a plurality of channel features, a metal gate, a first source/drain portion, and a second source/drain portion. The substrate has a (110) crystal plane. The plurality of channel features are disposed on the substrate. The metal gate is disposed to surround the plurality of channel features. The first source/drain portion and the second source/drain portion are disposed on the substrate and at two opposite sides of the metal gate. Each of the first source/drain portion and the second source/drain portion includes a base layer, a first intermediate layer, and an upper layer. The first intermediate layer is disposed on the base layer, and includes a bottom portion and two side portions extending from the bottom portion and spaced apart from each other. A thickness of each of the two side portions decreases in an upward direction from the substrate. The upper layer is disposed over the first intermediate layer.

In accordance with some embodiments of the present disclosure, each of the base layer, the first intermediate layer, and the upper layer is made of a semiconductor material including silicon germanium which contains germanium in a concentration.

In accordance with some embodiments of the present disclosure, the concentration of germanium in the base layer is lower than the concentration of germanium in the first intermediate layer, and the concentration of germanium in the first intermediate layer is lower than the concentration of germanium in the upper layer.

In accordance with some embodiments of the present disclosure, the semiconductor device further includes a plurality of silicon-based layers. Each of the plurality of silicon-based layers is doped with boron, and is disposed between a corresponding one of the channel features and the base layer.

In accordance with some embodiments of the present disclosure, the semiconductor device further includes a plurality of silicon-based layers. Each of the plurality of silicon-based layers is made of silicon doped with boron, and is disposed between the substrate and the base layer.

In accordance with some embodiments of the present disclosure, the semiconductor device further includes a second intermediate layer disposed between the first intermediate layer and the upper layer, and including a bottom portion and two side portions extending from the bottom portion and spaced apart from each other. A thickness of each of the two side portions of the second intermediate layer decreases in the upward direction.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a stack structure on a substrate, the stack structure including a plurality of sacrificial layer portions and a plurality of channel layer portions which are alternately stacked;
forming a trench that penetrates the stack structure;
forming a base layer in the trench;
forming an intermediate layer on the base layer and in the trench, the intermediate layer including a bottom portion and two side portions that extend from the bottom portion and that are spaced apart from each other, each of the two side portions including an upper part and a lower part interconnected to the upper part and the bottom portion;
removing the upper part of each of the two side portions of the intermediate layer; and
forming an upper layer over the intermediate layer.

2. The method as claimed in claim 1, wherein the substrate has a (110) crystal plane.

3. The method as claimed in claim 1, wherein the base layer is made of a semiconductor material including silicon germanium which contains germanium in a first germanium concentration ranging from 10% to 20%.

4. The method as claimed in claim 1, wherein the intermediate layer is made of a semiconductor material including silicon germanium which contains germanium in a second concentration ranging from 40% to 65%.

5. The method as claimed in claim 4, wherein the upper layer is made of a semiconductor material including silicon germanium which contains germanium in a third concentration ranging from 40% to 65%, wherein the third concentration is greater than the second concentration.

6. The method as claimed in claim 1, wherein removal of the upper part of the two side portions of the intermediate layer is performed using an etchant that includes hydrogen chloride, hydrogen radicals, chlorine radicals, fluorine radicals, or combinations thereof.

7. The method as claimed in claim 1, wherein each of the plurality of sacrificial layer portions includes silicon germanium.

8. The method as claimed in claim 7, wherein
the plurality of sacrificial layer portions are formed into a plurality of sacrificial features after formation of the trench;
the method further comprises, before formation of the base layer, replacing the plurality of sacrificial features with a plurality of interposers, respectively.

9. A method for manufacturing a semiconductor device, comprising:
forming two stack portions on a substrate, each of the stack portions including a plurality of sacrificial features and a plurality of channel features which are alternately stacked;
forming a base layer between the two stack portions, the base layer being formed on a side surface of each of the two stack portions and an upper surface of the semiconductor substrate;
forming a first intermediate layer on the base layer, the first intermediate layer including a bottom portion and two side portions that extend from the bottom portion and that are spaced apart from each other, each of the two side portions including an upper part and a lower part interconnected to the upper part and the bottom portion;
removing the upper part of each of the two side portions of the first intermediate layer; and
forming an upper layer over the first intermediate layer.

10. The method as claimed in claim 9, wherein each of the plurality of sacrificial features includes silicon germanium.

11. The method as claimed in claim 10, further comprising, before formation of the base layer, replacing the plurality of sacrificial features with a plurality of interposers, respectively.

12. The method as claimed in claim 9, further comprising, after formation of the first intermediate layer and before formation of the upper layer,
forming a second intermediate layer on the lower part of the each of the two side portions of the first intermediate layer, the second intermediate layer including a bottom portion and two side portions that extend from the bottom portion of the second intermediate layer and that are spaced apart from each other, each of the two side portions of the second intermediate layer including an upper part and a lower part interconnected to the upper part and the bottom portion of the second intermediate layer; and
removing the upper part of each of the two side portions of the second intermediate layer,
the upper layer being formed over the lower part of the each of the two side portions and the bottom portion of the second intermediate layer.

13. The method as claimed in claim 12, wherein each of the base layer, the first intermediate layer, the second intermediate layer, and the upper layer is made of a semiconductor material including silicon germanium which contains germanium in a concentration.

14. The method as claimed in claim 13, wherein the concentration of germanium in the base layer is lower than the concentration of germanium in the first intermediate layer, the concentration of germanium in the first intermediate layer is lower than the concentration of germanium in the second intermediate layer, and the concentration of germanium in the second intermediate layer is lower than the concentration of germanium in the upper layer.

15. A semiconductor device, comprising:
a substrate having a (110) crystal plane;
a plurality of channel features disposed on the substrate;
a metal gate disposed to surround the plurality of channel features; and
a first source/drain portion and a second source/drain portion disposed on the substrate and at two opposite sides of the metal gate, each of the first source/drain portion and the second source/drain portion including
a base layer,
a first intermediate layer disposed on the base layer and including a bottom portion and two side portions extending from the bottom portion and spaced apart from each other, a thickness of each of the two side portions decreasing in an upward direction from the substrate, and
an upper layer disposed over the first intermediate layer.

16. The semiconductor device as claimed in claim 15, wherein each of the base layer, the first intermediate layer, and the upper layer is made of a semiconductor material including silicon germanium which contains germanium in a concentration.

17. The semiconductor device as claimed in claim 16, wherein the concentration of germanium in the base layer is lower than the concentration of germanium in the first intermediate layer, and the concentration of germanium in the first intermediate layer is lower than the concentration of germanium in the upper layer.

18. The semiconductor device as claimed in claim 15, further comprising a plurality of silicon-based layers, each of the plurality of silicon-based layers being doped with boron, and being disposed between a corresponding one of the channel features and the base layer.

19. The semiconductor device as claimed in claim 15, further comprising a plurality of silicon-based layers, each of the plurality of silicon-based layers being doped with boron and being disposed between the substrate and the base layer.

20. The semiconductor device as claimed in claim 15, further comprising a second intermediate layer disposed between the first intermediate layer and the upper layer, and including a bottom portion and two side portions extending from the bottom portion and spaced apart from each other, a thickness of each of the two side portions of the second intermediate layer decreasing in the upward direction.
